(19) United States
(12) Patent Application Publication
(10) Pub. No.: US 2004/0137656 A1
(43) Pub. Date: Jul. 15, 2004

(54) Low thermal resistance light emitting diode package and a method of making the same

(76) Inventor: Gurbir Singh, Penang (MY)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/345,035

(22) Filed: Jan. 15, 2003

(51) Int. Cl. H01L 21/00; H01L 27/15

(52) U.S. Cl. 438/26; 257/79

(57) ABSTRACT

A method of manufacturing an LED includes a step of forming a conductive sheet that has at least an aperture and at least a pair of flanges that extend into the aperture. A tape is attached to a first side of the conductive sheet. A junction of an LED die is attached to a second side of the conductive sheet on one of the flanges. A conductor is connected from the other one of the flanges to an alternate junction of the LED die. The LED die, the conductor, and the pair of flanges are then encapsulated to form the LED unit. An LED manufactured in accordance with the above-mentioned method is also described.

### FIELD OF THE INVENTION

The present invention relates generally to Light Emitting Diodes (LEDs). More particularly, it relates to a low cost, low thermal resistance LED package that allows for an increase in brightness of the LED and a method of manufacturing the same.

### BACKGROUND

An existing method of manufacturing LEDs using surface mounted technology typically involves etching an array of leads onto a printed circuit board (PCB), such as a twenty-two by forty-two array. An LED p-n junction (also known as a die) is then attached to the PCB board. Usually, the connection of a die to a lead is provided by threading a conductor through a standard wire bonding capillary in a bond head and heating the end of the wire to form a ball. The ball is applied to a bond pad of the die to achieve the bond. The capillary is then moved to a lead with the wire being threaded to the capillary until the wire has reached the lead.

The wire is then stitch-bonded to the lead. To reduce the stress on the wire, the bond pad is typically looped above the bond pad. Regardless of the care taken, however, the wire is susceptible to damage due to the temperature stresses caused by the different expansion and contraction rates of the die and encapsulant (that is, different coefficients of thermal expansion). The amount of current provided to the LED must be limited to reduce the expansion stress caused by the heat output from the LED.

Finally, the LED is removed from the array by a cutting disk applied to interconnection strips between the LED and the PCB. A disadvantage of this step is the amount of time needed to cut and remove the LED. In addition, the cutting disks are also very expensive. Thus, the above-described process suffers from the disadvantages of being relatively expensive, time consuming, and having undesirable thermal properties.

In view of the above, a need clearly exists to manufacture an LED at a lower cost and having improved thermal properties.

### SUMMARY

An LED includes an LED p-n junction having a first and a second junction. A pair of electrically conductive heat dissipating flanges are provided, wherein a first flange of the pair of electrically conductive flanges is attached to the first junction. A conductor connects the second junction to a second flange of the pair of flanges. An encapsulating material seals the LED p-n junction and the conductor such that the LED has low thermal resistance and is made cost effectively.

A method of manufacturing an LED includes a step of forming a conductive sheet that has at least an aperture and at least a pair of flanges that extend into the aperture. A tape is attached to a first side of the conductive sheet. A junction of an LED die is attached to a second side of the conductive sheet on one of the flanges. A conductor is connected from the other one of the flanges to an alternate junction of the LED die. The LED die, the conductor, and the pair of flanges are then encapsulated to form the LED unit.

### BRIEF DESCRIPTION OF THE DRAWINGS

FIG. 1 is a plan view of a pre-form tape as a first intermediate form of an LED manufactured in accordance with the invention.

FIG. 2 is a plan view of a detailed portion of the tape of FIG. 1 showing the die attachment process.

FIG. 3 is a cross-sectional view of the tape of FIG. 2, as an encapsulated unit.

FIG. 4 is a cross-sectional view of the unit of FIG. 3 with the backing tape removed.

FIG. 5 is a flowchart of the steps of manufacturing an LED.

FIG. 6 is a schematic diagram of apparatus for manufacturing an LED embodying the invention.

### DETAILED DESCRIPTION

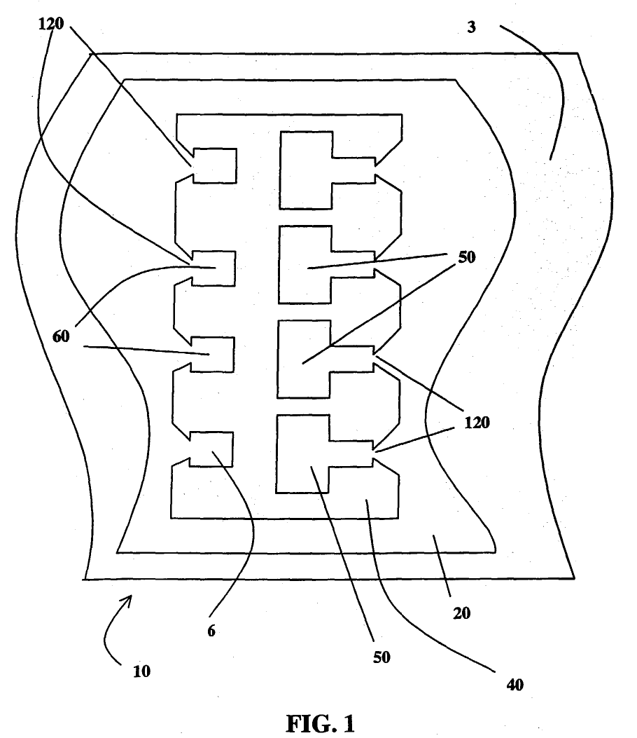

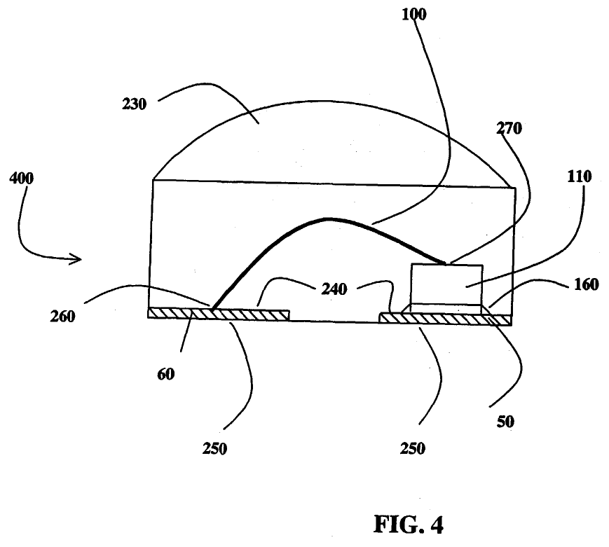

FIGS. 1-6 show a method of manufacturing an LED (e.g., LED 400) in accordance with one embodiment of the present invention. In addition, the FIGS. 1-6 show an LED manufactured by the method in accordance with one embodiment of the present invention. The method and the LED in accordance with one embodiment of the present invention will be described in more detail below, also in conjunction with FIGS. 1-6.

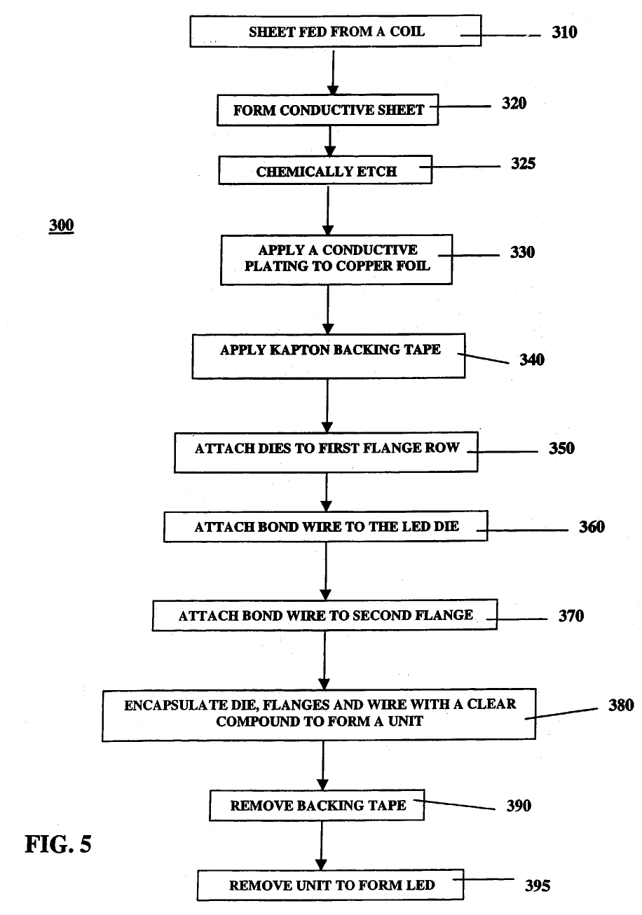

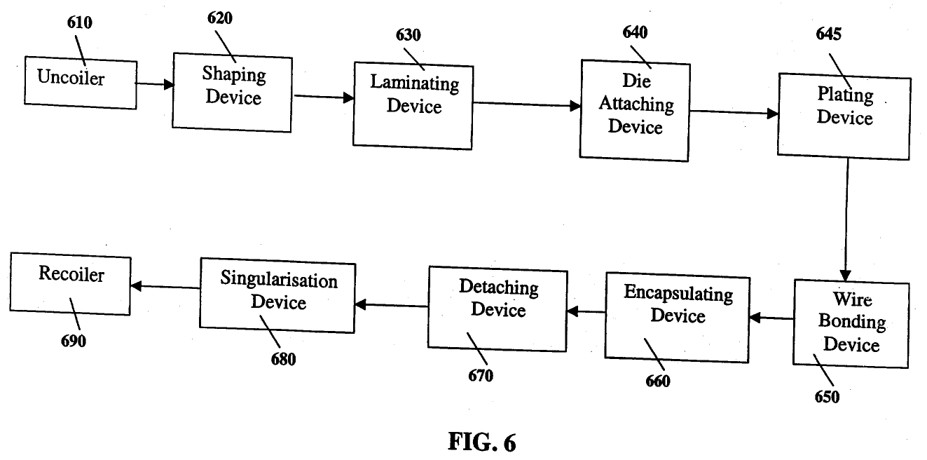

In the following description, FIGS. 1 to 4 show sequentially the partially fabricated LED by the method in accordance with one embodiment of the present invention. These figures should be read in conjunction with the flowchart of FIG. 5 and the block diagram of FIG. 6.

Referring to FIGS. 1-6, a coil of beryllium copper foil of 0.05 mm in thickness is fed from an uncoiler 610 (step 310) into a shaping device where the conductive sheet 20 is formed (step 325) from the copper foil to have at least one aperture 40 cut out to form at least a first flange 60 and a second flange 50 (step 320). The conductive sheet 20 may be formed by stamping or, alternatively, chemical etching.

The pair of flanges 50, 60 extend from the conductive sheet 20 into the aperture 40. There are a multiple apertures 40 in a given length of conductive sheet 20. A row of flange pairs 50, 60 correspond to each aperture. High stress concentration points 120, incorporated into each of the flanges 50, 60, connect each flange 50, 60 to the conductive sheet 20, as shown in FIG. 1. Different configurations may be chosen for particular manufacturing purposes.

The conductive sheet 20 is chemically etched (step 325), prior to applying a conductive plating (step 330) using a plating device 680. In some instances, the conductive sheet 20 will be selectively plated through masking locations where the plating is not required. The mask would then be removed by chemical treatment after plating (step 330).

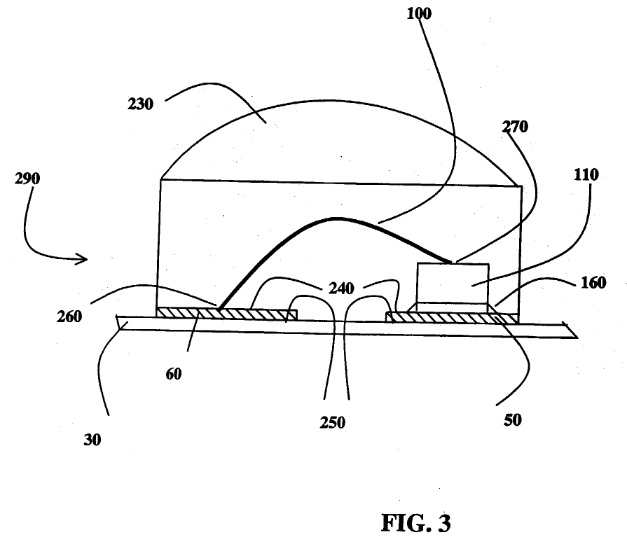

The conductive plating (step 330) is applied only to a first side 240, shown particularly in FIG. 3, of the conductive sheet (step 330). A conductive material will be chosen similar to the metallic component of the epoxy adhesive 160, so as to improve the reliability of bonding a LED die 110 (step 350) onto the conductive sheet 20. Conductive plating will also be used to improve the reliability of bonding the conductor 100 from the second flange 60 to the LED die 110.

The conductive sheet 20 is then fed into the lamination machine 630 which presses the Kapton™ tape onto the conductive sheet 20. The backing tape 30 is applied to a second side 250 of the conductive sheet 20 (step 340). A Dupont manufactured Kapton™ film is used as the backing tape 30. Advantageously, the Kapton™ tape has an adhesive backing, and is able to withstand temperatures above 200° C. A further advantage is the Kapton™ tape has desirable stability at high temperatures, with negligible emission of vapors. The tape 30 prevents the encapsulant 230 from contacting the second side 250 of the conductor sheet 20.

At this point, as shown particularly in FIG. 1, a pre-formed tape 10 is produced after the backing tape 30 is applied to the conductive sheet 20 (step 340). If desired, the pre-formed tape 10 can be stored as an intermediate form.

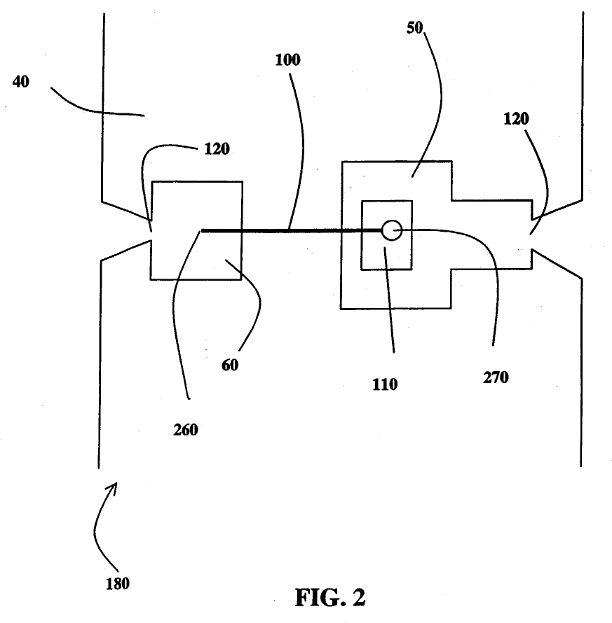

The intermediate preformed tape 10 is fed into the die attaching device 640 which attaches the LED die 110 onto the conductive sheet 20. The p-n junction of the LED, referred to as a LED die 110, is attached (step 350) at one junction 270 to the first flange 50, as shown particularly in FIGS. 2 and 3, using an epoxy adhesive 160. The epoxy adhesive has a high silver content for electrical conduction and thermal conduction. An array of dies is attached simultaneously, to reduce the time and cost of manufacture.

Prior to the attaching operation (step 350), the LED die 110 may have a gold pad bonded to the junction 270 by a plating device 645. Alternatively, the gold pad may be bonded to the junction 270 of the LED die 110 after the attaching operation (step 350) of the LED die 110 to the first flange 50. A gold pad is also soldered to the second flange 60. The gold pads improve the reliability of connection.

The plating device 645 feeds the partially formed LED into the wire bonding device 650 which connects the conductor 100 from the LED die 110 to the second flange 60. The conductor 100, otherwise known as a bonding wire, is attached to the second junction 270 of the LED die 110, by a suitable wire bonding process (step 360), as indicated particularly in FIG. 3. The conductor 100 is substantially comprised of gold for electrical conduction and reliable bonding. To reduce the time and cost of manufacture, a plurality of LED dies 110 is attached simultaneously to wire conductors 100.

Referring particularly to FIG. 3, the conductor 100 connects the second junction 270 of the LED die 110 to the second flange 60 by attaching the wire conductor 100 at the first side 240 of the second flange 60 by a suitable wire bonding process (step 370). To reduce the time and cost of manufacture, a row of second flanges 60 is attached to the conductors 100.

An encapsulating device 660 forms an encapsulant 230 over the partially formed LED to form a unit 290. The unit 290 is formed by encapsulating the LED die 110, the bonding conductor 100 and the flanges (50,60) with an encapsulant 230 (step 380). A suitable encapsulant 230 comprises of HYSOL™ epoxy MG 18, which is a clear epoxy compound and is fed by a transfer molding process. HYSOL™ is manufactured by the company Loctite, Inc., of the United States. The shape of the encapsulant 230 provides desirable optical characteristics by varying the location of the light intensity emitted from the LED die 110. The optical characteristics depend on the light intensity and the viewing angle.

The encapsulant 230 provides additional rigidity to the unit 290. The encapsulant 230 has low moisture absorption properties to reduce the likelihood of moisture and dirt entering the p-n junction of the LED 400. The encapsulant has a high glass transition temperature suitable for transfer molding.

After allowing the encapsulating compound to cure or harden to an extent, the backing tape 30 is removed (step 390). The unit 290 is fed to a detaching device 670 that removes the Kapton™ tape 30. In the reel-to-reel process line, a tension is applied to the backing tape 30 at an angle perpendicular to the horizontal motion of the conductive strip. Alternatively, the Kapton™ tape 30 may also be removed by hand. Advantageously, the Kapton™ tape 30 leaves low residue on the unit 290 when removed.

Once the backing tape 30 is removed, the unit 290 can be singularized (that is the unit 290 is removed from the conductive sheet 20) to form an LED 400 (step 395). A singularisation device 680 removes the unit 290 to form an LED 400. Each unit 290 is removed by applying a shear force that is transmitted to the flanges. As shown particularly by FIGS. 1 and 2, high stress concentration points 120 are incorporated into each of the flanges 50, 60. A shear force transmitted will cause the unit 290 to separate from the conductive sheet 20 at the high stress concentration point 120.

A recoiler 690 wraps the waste copper foil into a coil and may be used to provide tension on the line.

The LED 400 so formed is of Small Form Factor and leadless. The copper in the LED 400 provides, advantageously, a relatively low thermal resistance and thus is able to dissipate heat relatively quickly in comparison to some prior art forms of LED. The ability to dissipate heat quickly allows the power supplied to the LED 400 to be increased, without causing the same expansion stresses to be placed onto the various components of the LED 400. As the power supplied to the LED 400 can be increased, in comparison to some prior forms of LEDs, the light output of the LED 400 is also increased.

A small number of embodiments for manufacturing an LED have been described. Various modifications and/or changes can be made thereto without departing from the scope and spirit of the invention, the embodiments being illustrative and not restrictive.

1. A method of manufacturing a Light Emitting Diode (LED), comprising:
forming a conductive sheet that has at least an aperture and at least a pair of flanges which extend into said aperture;
attaching a tape to a first side of said conductive sheet;
attaching a junction of a LED die to a second side of said conductive sheet on one of said pair of flanges;
connecting a conductor from the other one of said pair of flanges to an alternate junction of said LED die;
encapsulating said LED die, said conductor, and said pair of flanges to form the Led:

2. The method of claim 1, further comprising
detaching said tape from said conductive sheet; and
separating the conductive sheet from the LED at the flanges.

3. The method as claimed in claim 1, wherein the step encapsulating further comprises the step of applying to the second side of the conductive sheet a clear molding compound which is constrained by said tape, wherein the clear molding compound is applied using a transfer molding process.

4. The method as claimed in claim 2, wherein the step of separating further comprises the step of applying a force that is transmitted to the flanges to separate said flanges from said conductive sheet.

5. The method as claimed in claim 1, wherein the step of forming further comprises the step of chemically etching a copper foil to form said conductive sheet with the aperture and the pair of flanges.

6. The method of claim 1, further comprising the step of applying a conductive material to said conductive sheet to assist in attaching said LED die to said first flange

7. The method of claim 1, wherein the step attaching further comprises the step of supplying and receiving said conductive sheet and said tape from a reel-to-reel production line.

8. The method of claim 7, further comprising the step of applying a second conductive material to said conductive sheet and said alternate junction, prior to the step of attaching, to assist in the attaching of said conductor.

9. A light emitting diode (LED), comprising:
a LED p-n junction having a first and a second junction;
a pair of electrically conductive heat dissipating flanges, a first flange of the pair of electrically conductive flanges being attached to said first junction of said LED p-n junction;
a conductor connecting said second junction of the LED p-n junction to a second flange of the pair of flanges; and
an encapsulant sealing said LED p-n junction and said conductor.

10. The LED of claim 9, wherein the flanges are formed by chemically etching a copper foil.

11. The LED of claim 9, wherein the flanges are further coated with a conductive material to assist in attaching said LED die to said first flange.

12. The LED of claim 9, wherein a second conductive material is applied to said second flange and said second junction to assist in the attaching of said conductor to the second junction and the second flange.

13. An LED apparatus manufactured by a method that comprises the steps of:
forming a conductive sheet that has at least an aperture and at least a pair of flanges which extend into said aperture;
attaching a tape to a first side of said conductive sheet;
attaching a junction of a LED die to a second side of said conductive sheet on one of said pair of flanges;
connecting a conductor from the other one of said pair of flanges to an alternate junction of said LED die;
encapsulating said LED die, said conductor, and said pair of flanges to form the LED.

14. The LED apparatus of claim 13, further comprising
detaching said tape from said conductive sheet; and
separating the conductive sheet from the LED at the flanges.

15. The LED apparatus of claim 13, wherein the step encapsulating further comprises the step of applying to the second side of the conductive sheet a clear molding compound which is constrained by said tape, wherein the clear molding compound is applied using a transfer molding process.

16. The LED apparatus of claim 14, wherein the step of separating further comprises the step of applying a force that is transmitted to the flanges to separate said flanges from said conductive sheet.

17. The LED apparatus of claim 13, wherein the step of forming further comprises the step of chemically etching a copper foil to form said conductive sheet with the aperture and the pair of flanges.

18. The LED apparatus of claim 13, wherein the steps further comprise the step of applying a second conductive material to said conductive sheet and said alternate junction, prior to the step of attaching, to assist in the attaching of said conductor.
